(19) United States
(12) Patent Application Publication
(10) Pub. No.: US 2026/0026269 A1
(43) Pub. Date: Jan. 22, 2026

(54) SEMICONDUCTOR DEVICE INCLUDING RESISTANCE CHANGE LAYER AND THERMAL CONFINEMENT ELECTRODE LAYER

(71) Applicant: SK hynix Inc., Icheon-si (KR)

(72) Inventors: Sang Min LEE, Icheon-si (KR); Ka Young KIM, Icheon-si (KR); Sang Su PARK, Icheon-si (KR); Jae Yun YI, Icheon-si (KR)

(73) Assignee: SK hynix Inc., (omitted)

(21) Appl. No.: 18/908,390

(22) Filed: Oct. 7, 2024

(30) Foreign Application Priority Data
Jul. 16, 2024 (KR) 10-2024-0094042

(51) Int. Cl. H10N 70/00

(52) U.S. Cl. CPC H10N 70/8616; H10N 70/8833

(57) ABSTRACT

A semiconductor device includes a first electrode, a resistance change layer disposed on the first electrode and including oxygen vacancies, an oxygen vacancy reservoir layer disposed on the resistance change layer, a thermal confinement electrode layer disposed on the oxygen vacancy reservoir layer, and a second electrode disposed on the thermal confinement electrode layer.

### CROSS-REFERENCE TO RELATED APPLICATION

The present application claims priority under 35 U.S.C. § 119(a) to Korean Application No. 10-2024-0094042, filed in the Korean Intellectual Property Office on Jul. 16, 2024, which is incorporated herein by reference in its entirety.

### BACKGROUND

### 1. Technical Field

The present disclosure generally relates to a semiconductor device including a resistance change layer.

### 2. Related Art

In general, a resistance change material refers to a material whose electrical resistance changes when an external stimulus such as heat, current, voltage, or light is applied. The resistance change material can maintain its altered electrical resistance even after the external stimulus is removed. A product that utilizes the electrical characteristics of a resistance change material to store signal information is a resistance change memory device.

In a resistance change memory device, the resistance state of a memory layer can switch between a low resistance state and a high resistance state through a set operation and a reset operation. Depending on the factor causing the switching operation, the resistance change memory device can be classified into a resistive memory (Resistive RAM), a phase change memory (Phase Change RAM), a magnetic memory (Magnetic RAM), etc. In some resistance change memory devices, a filament-based resistive memory (Resistive RAM) can implement different resistance states by generating or disconnecting conductive filaments, which provide low resistance within a resistive switching layer when voltage or current is applied to both ends of the resistive switching layer. Recently, a technology for storing multiple levels of signal information by implementing multiple resistance states within a resistance change layer has been studied. Discussions about this technology include the possibility of applying the technology for storing multiple levels of signal information in a cell structure for analog calculations in neuromorphic devices.

### STATEMENT REGARDING PRIOR DISCLOSURES BY THE INVENTOR OR A JOINT INVENTOR

At least one inventor or joint inventor of the present disclosure has made related disclosures in 2023 International Electron Device Meeting (IEDM) at IEEE on Dec. 9, 2023.

### SUMMARY

A semiconductor device according to an embodiment of the present disclosure may include a first electrode, a resistance change layer disposed on the first electrode and including oxygen vacancies, an oxygen vacancy reservoir layer disposed on the resistance change layer, a thermal confinement electrode layer disposed on the oxygen vacancy reservoir layer, and a second electrode disposed on the thermal confinement electrode layer.

A semiconductor device according to another embodiment of the present disclosure may include a contact plug electrode, a first thermal confinement electrode layer disposed on the contact plug electrode, a first electrode disposed on the first thermal confinement electrode layer, a resistance change layer comprising oxygen vacancies and disposed on the first electrode, an oxygen vacancy reservoir layer disposed on the resistance change layer, and a second electrode disposed on the oxygen vacancy reservoir layer.

### BRIEF DESCRIPTION OF THE DRAWINGS

FIG. 1 is a schematic cross-sectional view illustrating a semiconductor device according to an embodiment of the present disclosure.

FIG. 2A and FIG. 2B are schematic cross-sectional views illustrating a resistance change layer according to an embodiment of the present disclosure.

FIG. 3 is a schematic view illustrating the flow of internal heat during operation of a semiconductor device according to an embodiment of the present disclosure.

FIG. 4 is a schematic cross-sectional view illustrating a semiconductor device according to another embodiment of the present disclosure.

FIG. 5 is a schematic cross-sectional view illustrating a semiconductor device according to another embodiment of the present disclosure.

FIG. 6 is a schematic cross-sectional view illustrating a semiconductor device according to another embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Terms used in the specification of the present application are terms selected in consideration of functions in the presented embodiments, and the meaning of the terms may vary depending on the intention or customs of a user or operator in the technical field. The meanings of the terms used follow the definitions defined when specifically defined herein, and may be interpreted as meanings generally recognized by those skilled in the art in the absence of specific definitions.

Semiconductor devices according to embodiments of the present disclosure include a resistance change layer disposed between a pair of electrodes. The resistance change layer can store multiple conductance values (or electrical resistances) that can be distinguished from each other. Additionally, the semiconductor devices include a thermal confinement electrode layer that mitigates the release of heat generated during device operation as the heat is released to the outside of the semiconductor device. The thermal confinement electrode layer has a lower thermal conductivity than an adjacent electrode, thereby helping to keep the heat generated during the set operation and reset operation of the semiconductor device inside of the semiconductor device.

The semiconductor devices according to embodiments of the present disclosure can be applied to analog computing in memory (hereinafter, referred to as “ACiM”). As an example, the semiconductor devices can be used in cells of a cell array device that stores consecutive weights and performs a vector matrix multiplication. That is, the semiconductor devices can be utilized as a memristor-based synaptic element in devices implementing neuromorphic technology.

In a published paper (“A Holistic Methodology Toward Large-scale AI Implementation using Realistic ReRAM based ACiM from Cell to Architecture, 2023 International Electron Devices Meeting (IEDM), 09-13 December, 2023”, hereinafter the “Paper”), the inventor of the present disclosure disclosed a configuration of a resistive RAM device having a thermal enhanced layer. The configuration of the resistive RAM device and the AciM based on the resistive memory device disclosed in the Paper, and the Paper itself, are incorporated by reference as though fully set forth herein.

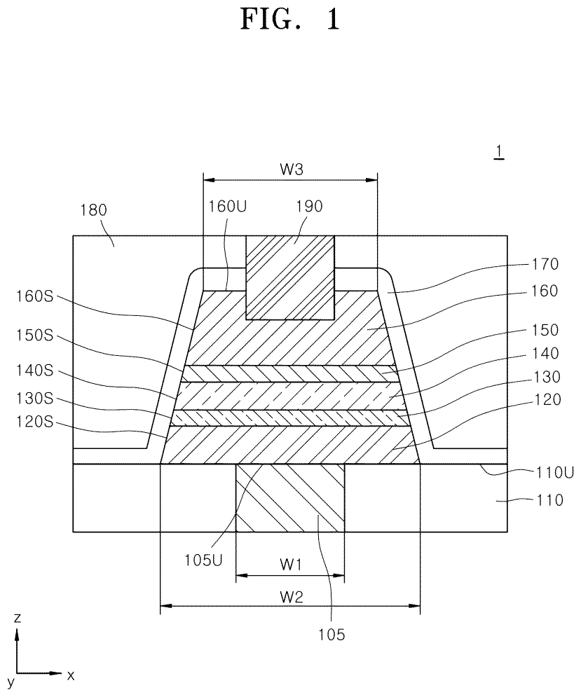

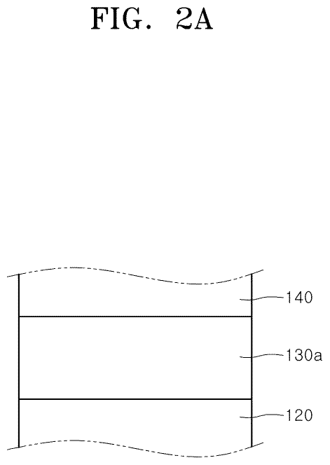

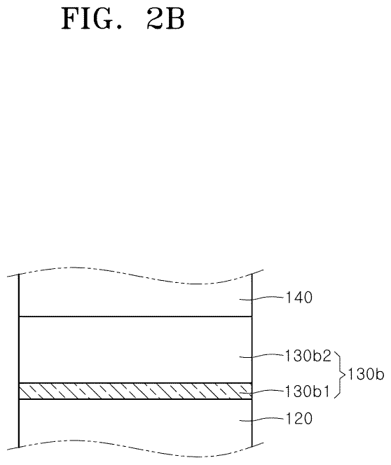

FIG. 1 is a schematic cross-sectional view illustrating a semiconductor device according to an embodiment of the present disclosure. FIG. 2A and FIG. 2B are schematic cross-sectional views illustrating a resistance change layer according to an embodiment of the present disclosure.

Referring to FIG. 1, a semiconductor device 1 includes a first electrode 120, a resistance change layer 130 disposed on the first electrode 120, an oxygen vacancy reservoir layer 140 disposed on the resistance change layer 130, a thermal confinement electrode layer 150 disposed on the oxygen vacancy reservoir layer 140, and a second electrode 160 disposed on the thermal confinement electrode layer 150. In addition, the semiconductor device 1 includes a contact plug electrode 105 and a contact electrode 190 that are electrically connected to the first electrode 120 and the second electrode 160, respectively.

The semiconductor device 1 may be disposed over a substrate (not shown). The substrate may include an insulating material, a conductive material, or a semiconductor material in which a semiconductor integration process can proceed. In an embodiment, the substrate may be a silicon substrate doped with an n-type or p-type dopant.

Referring to FIG. 1, the semiconductor device 1 includes the contact plug electrode 105 disposed over the substrate. The contact plug electrode 105 is electrically connected to the substrate and the first electrode 120. The contact plug electrode 105 may include, for example, metal, metal nitride, metal silicide, or a combination of two or more thereof. The contact plug electrode 105 is disposed to be surrounded by a base insulation layer 110 in a lateral direction (for example, x-direction or y-direction). The base insulation layer 110 may include, for example, oxide, nitride, oxynitride, or a combination two or more thereof. An upper surface 110U of the base insulation layer 110 may be substantially flat and may be positioned at substantially the same level as an upper surface 105U of the contact plug electrode 105.

In an embodiment, a selection transistor may be disposed over the substrate. The selection transistor may include a source electrode, a gate electrode, and a drain electrode. The source electrode may be electrically connected to a source line providing an operation voltage or a ground voltage, and the drain electrode may be electrically connected to the contact plug electrode 105. When the selection transistor is turned on, the source line may be electrically connected to the contact plug electrode 105 via a conductive channel formed under the gate electrode. In another embodiment, the selection transistor is excluded, and the source line may be directly connected to the contact plug electrode 105. As an example, the source line may be disposed over the substrate, and the contact plug electrode 105 may be disposed on the source line. The contact plug electrode 105 may include a conductive material. The conductive material may include, for example, metal, conductive metal nitride, conductive metal silicide, or a combination of two or more thereof.

Referring to FIG. 1, the first electrode 120 is disposed on the contact plug electrode 105 and the base insulation layer 110. The first electrode 120 is disposed to overlap with the contact plug electrode 105 in the z-direction. The first electrode 120 is disposed to cover the contact plug electrode 105. In one lateral direction (for example, x-direction), a width W2 of the first electrode 120 may be larger than a width W1 of the contact plug electrode 105.

The first electrode 120 may include a conductive material. The conductive material may include, for example, metal, conductive metal nitride, conductive metal carbide, conductive metal silicide, or conductive metal oxide. The conductive material may include, for example, platinum (Pt), gold (Au), tantalum (Ta), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

The resistance change layer 130 is disposed on the first electrode 120. The resistance change layer 130 may include a resistance change material whose conductance (or electrical resistance) changes depending on an applied voltage or applied current. In addition, the resistance change material may maintain the changed conductance (or the changed electrical resistance) in a non-volatile manner after the applied voltage or applied current is removed.

In an embodiment, the resistance change layer 130 stores a plurality of distinct conductance values as signal information. As an example, the plurality of conductance values have a relationship in which the magnitude of the conductance values changes substantially linearly in relation to the magnitude of the applied operation voltage. The magnitude of the applied operation voltage may be controlled, for example, by the amplitude of a direct current (DC) voltage, the width of a pulse voltage, or the number of times the pulse voltage is applied.

In an embodiment, the resistance change material of the resistance change layer 130 may include oxygen vacancies. The resistance change material may include metal oxide that does not satisfy a stoichiometric ratio. The resistance change material may include, for example, hafnium oxide, zirconium oxide, hafnium zirconium oxide, titanium oxide, aluminum oxide, or a combination of two or more thereof.

The oxygen vacancies may operate as follows during a set operation or reset operation of the semiconductor device 1. For example, when a set voltage for a set operation is applied between the first electrode 120 and the second electrode 160, an electric field is formed in the resistance change layer 130 due to the set voltage. Oxygen vacancies aggregate along the electric field so that conductive filaments are formed in the thickness direction (that is, z-direction) of the resistance change layer 130. The conductive filaments may increase the conductance of the resistance change layer 130 by providing a path for conductive carriers to move in the z-direction through the resistance change layer 130. The width and distribution of the conductive filaments may vary depending on the magnitude of the applied set voltage. The conductance of the resistance change layer 130 may increase in proportion to the width and density of the conductive filaments. In another example, when a reset voltage for the reset operation is applied between the first electrode 120 and the second electrode 160, oxygen vacancies are separated from previously formed conductive filaments, and accordingly, the conductive filaments degrade and are electrically disconnected. The polarity of the reset voltage may be opposite to the polarity of the set voltage. By disconnecting the conductive filaments, the conductance of the resistance change layer 130 may decrease.

The resistance change layer 130 may have a single-layer or multi-layer structure. As an example of the resistance change layer 130 of FIG. 1, FIG. 2A and FIG. 2B schematically illustrate structures of resistance change layers 130a and 130b disposed between the first electrode 120 and the oxygen vacancy reservoir layer 140.

Referring to FIG. 2A, a resistance change layer 130a has a single layer structure. The resistance change layer 130a has a thickness that ranges from 10 Å (angstroms) through 100 Å. The resistance change layer 130a may include, for example, hafnium oxide, zirconium oxide, hafnium zirconium oxide, or a combination of two or more thereof.

Referring to FIG. 2B, a resistance change layer 130b includes a first layer 130b1 and a second layer 130b2. The first layer 130b1 is disposed to contact the first electrode 120, and the second layer 130b2 is disposed on the first layer 130b1. The first layer 130b1 may include aluminum oxide. The first layer 130b1 has a thickness within a range of 2 Å through 10 Å. The second layer 130b2 may include, for example, hafnium oxide, zirconium oxide, hafnium zirconium oxide, or a combination of two or more thereof. The second layer 130b2 has a thickness within a range of 10 Å through 100 Å.

The first layer 130b1 has a lower concentration of oxygen vacancies than the second layer 130b2, and the first layer 130b1 has a relatively dense structure. The first layer 130b1 may serve as a barrier to prevent oxygen exchange between the first electrode 120 and the second layer 130b2 when a reset operation, in which the conductive filaments are disconnected, is performed. Because the first layer 130b1 serves as the barrier to oxygen when the reset operation, the occurrence of a negative-set phenomenon may be delayed. The negative-set phenomenon means that when the reset voltage increases, the oxygen vacancies in the disconnected conductive filaments re-aggregate, leading to re-growth of the conductive filaments. In this way, the first layer 130b1 can enhance the ability of the resistance change layer 130 to resist electrical breakdown, thereby improving the electrical reliability of the resistance change layer 130.

Referring back to FIG. 1, the oxygen vacancy reservoir layer 140 is disposed on the resistance change layer 130. The oxygen vacancy reservoir layer 140 may provide oxygen vacancies to the resistance change layer 130 when a forming voltage or a set voltage is applied between the first electrode 120 and the second electrode 160. In addition, the oxygen vacancy reservoir layer 140 may receive the oxygen vacancies from the resistance change layer 130 when a reset voltage is applied between the first electrode 120 and the second electrode 160. The polarity of the reset voltage may be opposite to the polarities of the forming voltage and the set voltage.

In an embodiment, the oxygen vacancy reservoir layer 140 may include metal having reactivity with oxygen. The metal may include, for example, tantalum (Ta), titanium (Ti), zirconium (Zr), vanadium (V), tungsten (W), ruthenium (Ru), or a combination of two or more thereof.

Referring to FIG. 1, the thermal confinement electrode layer 150 is disposed on the oxygen vacancy reservoir layer 140. The thermal confinement electrode layer 150 may perform the role of preventing heat from being conducted to the second electrode 160 through the thermal confinement electrode layer 150. In addition, the thermal confinement electrode layer 150 may function as an electrode of the semiconductor device 1 when together with the second electrode 160. That is, in the semiconductor device 1 of FIG. 1, the first electrode 120 may function as a lower electrode, and the thermal confinement electrode layer 150 and the second electrode 160 may function as upper electrodes.

The thermal confinement electrode layer 150 may include an electrode material having lower thermal conductivity than the material of the second electrode 160. The electrode material may be a resistor having a predetermined electrical conductivity. As an example, the thermal confinement electrode layer 150 has a thickness within a range of 10 Å through 100 Å.

In an embodiment, thermal confinement electrode layer 150 may include metal silicon nitride. As an example, the thermal confinement electrode layer 150 may include tungsten silicon nitride, titanium silicon nitride, aluminum silicon nitride, or a combination of two or more thereof. In another embodiment, the thermal confinement electrode layer 150 may contain carbon (C). As an example, the thermal confinement electrode layer 150 may include a carbon layer. The carbon layer may have, for example, an amorphous structure. The carbon layer may be, for example, doped with nitrogen (N). The carbon layer may be controlled to have different thermal conductivities, while having substantially the same electrical conductivity, depending on a doping method or a deposition method. In an embodiment of the present disclosure, the carbon layer may be formed to have reduced thermal conductivity relative to other layers in the device.

The thermal confinement electrode layer 150 can prevent the heat generated in the resistance change layer 130 and the oxygen vacancy reservoir layer 140 from being transferred to the contact electrode 190 through the second electrode 160 and from escaping to the outside of the semiconductor device 1 thereafter. The heat generated in the resistance change layer 130 and the oxygen vacancy reservoir layer 140 results from operations such as the set operation and the reset operation of the semiconductor device 1. The thermal confinement electrode layer 150 can maintain or preserve the heat within the resistance change layer 130 and the oxygen vacancy reservoir layer 140.

Referring to FIG. 1, the second electrode 160 is disposed on the thermal confinement electrode layer 150. The second electrode 160 may include a conductive material. The second electrode 160 may include, for example, metal, conductive metal nitride, conductive metal carbide, conductive metal silicide, or conductive metal oxide. The conductive material of the second electrode 160 may be the same as or different from the conductive material of the first electrode 120.

A width W3 of the second electrode 160 may be smaller than the width W2 of the first electrode 120 in a lateral direction (for example, the x-direction). Referring to FIG. 1, the width in the lateral direction may decrease for each layer from the first electrode 120 to the second electrode 160. Accordingly, the semiconductor device 1 shown in FIG. 1 may have a trapezoidal cross-sectional shape.

Referring to FIG. 1, a protective insulation layer 170 is disposed on the base insulation layer 110. The protective insulation layer 170 is disposed to cover a side surface 120S of the first electrode 120, a side surface 130S of the resistance change layer 130, a side surface 140S of the oxygen vacancy reservoir layer 140, a side surface 150S of the thermal confinement electrode layer 150, and a side surface 160S and an upper surface 160U of the second electrode 160. The side surfaces may form a surface that continuously tapers from the side surface 120S through the side surface 160S. The protective insulation layer 170 can serve as a barrier to prevent materials from diffusing from outside of the semiconductor device 1 into the semiconductor device 1. The protective insulation layer 170 may include an insulating material having a denser structure than an interlayer insulation layer 180 (described below) in order to perform the function of a barrier. The insulating material may include, for example, silicon oxide, silicon nitride, or silicon oxynitride.

Referring to FIG. 1, the interlayer insulation layer 180 is disposed to cover the protective insulation layer 170, which is disposed on the base insulation layer 110. The interlayer insulation layer 180 may include an electrically insulating material. The interlayer insulation layer 180 has a flattened upper surface common to an upper surface of the contact electrode 190. The interlayer insulation layer 180 may include an insulating material having a low dielectric constant, for example, oxide, nitride, or oxynitride.

The contact electrode 190 is disposed to penetrate the protective insulation layer 170 and the interlayer insulation layer 180 and to contact the second electrode 160. The contact electrode 190 may include a conductive material. The contact electrode 190 may include, for example, metal, conductive metal nitride, conductive metal carbide, conductive metal silicide, or conductive metal oxide. The contact electrode 190 may be connected to a bit line that applies an operation voltage.

As described above, semiconductor devices according to embodiments of the disclosure include a first electrode, a resistance change layer disposed on the first electrode, an oxygen vacancy reservoir layer disposed on the resistance change layer, a thermal confinement electrode layer disposed on the oxygen vacancy reservoir layer, and a second electrode disposed on the thermal confinement electrode layer. The thermal confinement electrode layer has lower thermal conductivity than an adjacent second electrode, thereby helping to confine the heat generated during set operations and reset operations inside the semiconductor device.

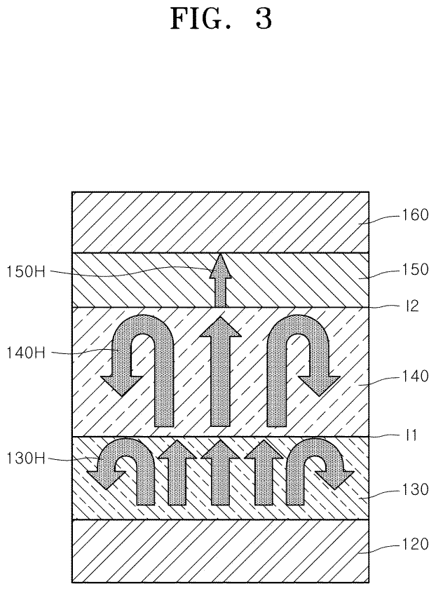

FIG. 3 is a schematic diagram illustrating the flow of internal heat during an operation of a semiconductor device according to an embodiment of the present disclosure. The schematic diagram of FIG. 3 schematically illustrates the flow of the heat generated inside a semiconductor device 1 of FIG. 1 when a set operation or a reset operation is performed in the semiconductor device 1.

Referring to the schematic diagram of FIG. 3, when a set voltage or a reset voltage is applied to the resistance change layer 130, the heat generated in the resistance change layer 130 may move toward the oxygen vacancy reservoir layer 140. A portion of the generated heat may pass through an interface I1 between the resistance change layer 130 and the oxygen vacancy reservoir layer 140, and transfer into the oxygen vacancy reservoir layer 140. Another portion of the generated heat might not move into the oxygen vacancy reservoir layer 140 and remain in the resistance change layer 130. In FIG. 3, the flow of the generated heat within the resistance change layer 130 is indicated as “130H.”

The heat inside the oxygen vacancy reservoir layer 140 transferred from the resistance change layer 130 may move to an interface 12 between the oxygen vacancy reservoir layer 140 and the thermal confinement electrode layer 150. Most of the heat that moves to the interface 12 is blocked by the thermal confinement electrode layer 150, which has low thermal conductivity, and remain inside the oxygen vacancy reservoir layer 140. As the temperature of the oxygen vacancy reservoir layer 140 increases, the flow of the heat from the resistance change layer 130 to the oxygen vacancy reservoir layer 140 may decrease.

Meanwhile, a portion of the heat inside the oxygen vacancy reservoir layer 140 may pass through the interface 12 and move into the thermal confinement electrode layer 150. Because the thermal conductivity of the thermal confinement electrode layer 150 is low, the flow of the heat moving toward the second electrode 160 within the thermal confinement electrode layer 150 may be limited. In FIG. 3, the heat flow within the oxygen vacancy reservoir layer 140 and the heat flow within the thermal confinement electrode layer 150 are indicated as “140H” and “150H”, respectively.

Because the thermal confinement electrode layer 150 is disposed between the oxygen vacancy reservoir layer 140 and the second electrode 160, thermal energy can accumulate in the resistance change layer 130 during operations of the semiconductor device (1 of FIG. 1). Accordingly, the internal temperature of the resistance change layer 130 can be higher when compared to a device in which the thermal confinement electrode layer 150 is not provided.

When the internal temperature of the resistance change layer 130 rises, the formation and disconnection of conductive filaments within the resistance change layer 130 becomes more stable and uniform. As the internal temperature rises, the distribution of oxygen vacancies within the resistance change layer may become more uniform. Accordingly, during the forming operation or set operation of the semiconductor device (1 in FIG. 1), multiple weaker filaments may be formed with a relatively higher probability than a single stronger filament within the resistance change layer 130. A strong filament may mean a filament having a large width and a large cross-sectional area, and a weak filament may mean a filament having a relatively small width and a relatively small cross-sectional area. Accordingly, when a resistance switching operation occurs within the resistance change layer 130 of the semiconductor device, and multiple weak filaments are formed, the change in conductance may occur gradually rather than abruptly. As a result, the linearity between the plurality of conductance values stored in the semiconductor device may be improved, thereby improving the analog characteristics of the stored signal information.

In the above-described Paper of the inventor of the present disclosure, a ReRAM synapse cell (RSC) having a thermal enhanced layer corresponding to the thermal confinement electrode layer of an embodiment of the present disclosure is disclosed. The RSC having the thermal enhanced layer can have improved resistance switching characteristics, compared to an RSC without the thermal enhanced layer. As an example, in the RSC described in the Paper, a forming voltage V_{Form}, which is the voltage at which the first conductive filament is generated through the forming operation, may decrease. The forming voltage decreases because as the internal temperature of the resistance change layer 130 rises, the aggregation of the oxygen vacancies is promoted so that the conductive filament is generated at a relatively low voltage.

Additionally, compared to an RSC without a thermal enhancement layer, in the RSC with the thermal enhancement layer, the breakdown voltage V_{BD} may relatively increase. The breakdown voltage V_{BD} may refer to a voltage at which a negative-set phenomenon occurs during a reset operation. The negative-set phenomenon may refer to a phenomenon in which the conductive filaments disconnected through the reset operation re-grow through re-aggregation of the oxygen vacancies. In an example, a negative-set phenomenon may be confirmed from the fact that, during a reset operation, the conductance value of the resistance change layer rapidly increases when the reset voltage reaches a voltage greater than a predetermined level.

In addition, according to the above-described Paper, an RSC having a thermal enhancement layer can improve data linearity for multiple weights compared to an RSC without a thermal enhancement layer. For example, the weights can be numbers stored in the RSC for a multiplication and accumulation (MAC) operation.

In the above-described Paper, the improvement of the data linearity is confirmed through the following process. First, multiple target weights (that is, ideal outputs) that change linearly are set, and operation voltages that implement the multiple target weights are determined. The operation voltages may be applied to the RSCs to confirm deviations between the actually measured weights (that is, the real outputs) and the target weights (that is, the ideal outputs). In the Paper, it can be confirmed that the RSCs with thermal enhancement layers have a smaller deviation between the target weight and the measured weight at multiple operation voltages compared to the RSCs without thermal enhancement layers. The improvement in the data linearity may mean that the analog characteristics of the RSC are improved.

Additionally, according to the Paper, the RSCs with a thermal enhancement layer can have improved data retention over time, compared to the RSCs without a thermal enhancement layer. In other words, the Paper confirms that the RSCs with a thermal enhancement layer have relatively superior weight degradation characteristics after a predetermined period of time, compared to the RSCs without a thermal enhancement layer.

In conclusion, semiconductor devices of embodiments of the present disclosure include a thermal confinement electrode layer to improve resistance switching characteristics such as forming voltage, breakdown voltage, etc. and to improve reliability in data linearity, information retention, etc.

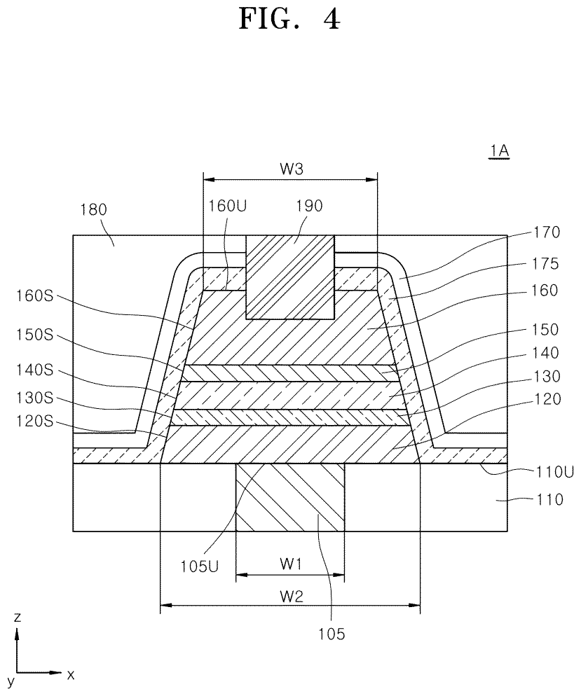

FIG. 4 is a schematic cross-sectional view illustrating a semiconductor device according to another embodiment of the present disclosure. Referring to FIG. 4, a semiconductor device 1A further includes a thermal confinement insulation layer 175, compared to a semiconductor device 1 described above with reference to FIG. 1.

The thermal confinement insulation layer 175 is disposed to cover a side surface 120S of a first electrode 120, a side surface 130S of a resistance change layer 130, a side surface 140S of an oxygen vacancy reservoir layer 140, a side surface 150S of a thermal confinement electrode layer 150, and a side surface 160S and an upper surface 160U of an second electrode 160. Specifically, the thermal confinement insulation layer 175 is disposed to contact the first electrode 120, the resistance change layer 130, the oxygen vacancy reservoir layer 140, the thermal confinement electrode layer 150, and the second electrode 160. The thermal confinement insulation layer 175 is a layer that can further limit the release of heat inside a semiconductor device 1A from being released through the side surfaces 120S, 130S, 140S, 150S, and 160S and through the upper surface 160U of the second electrode 160.

The thermal confinement insulation layer 175 may include a dielectric having low thermal conductivity. The thermal confinement insulation layer 175 may include, for example, an oxide dielectric or an organic dielectric material. Specifically, the thermal confinement insulation layer 175 may include a fluorine-doped silicon oxide, a carbon-doped silicon oxide, a metal-organic framework, and the like. The thermal confinement insulation layer 175 may have a porous structure. The thermal confinement insulation layer 175 may have electrically insulating properties.

A protective insulation layer 170 is disposed on the thermal confinement insulation layer 175. The protective insulation layer 170 may include an insulating material of a relatively dense structure having a higher density than the thermal confinement insulation layer 175. The protective insulation layer 170 may include a different insulating material from the thermal confinement insulation layer 175. The insulating material of the protective insulation layer 170 may include, for example, silicon oxide, silicon nitride, or silicon oxynitride.

An interlayer insulation layer 180 is disposed on the protective insulation layer 170. A contact electrode 190 is disposed to penetrate the interlayer insulation layer 180, the protective insulation layer 170, and the thermal confinement insulation layer 175 and to contact the second electrode 160.

In some embodiments, the protective insulation layer 170 may be omitted, and the interlayer insulation layer 180 is disposed to directly contact the thermal confinement insulation layer 175.

Although not illustrated, other embodiments may include thermal confinement insulation layers 175 with various variations. For example, the thermal confinement insulation layer 175 may be disposed to cover at least the side surfaces 130S and 140S of the resistance change layer 130 and the oxygen vacancy reservoir layer 140, respectively, but not disposed to cover at least one of the side surface 120S of the first electrode 120, the side surface 150S of the thermal confinement electrode layer 150, and the side surface 160S and the upper surface 160U of the second electrode 160. In this case, the protective insulation layer 170 or the interlayer insulation layer 180 may be disposed directly on the at least one of the side surface 120S of the first electrode 120, the side surface 150S of the thermal confinement electrode layer 150, and the side surface 160S and the upper surface 160U of the second electrode 160, that is, where the thermal confinement insulation layer 175 is not disposed.

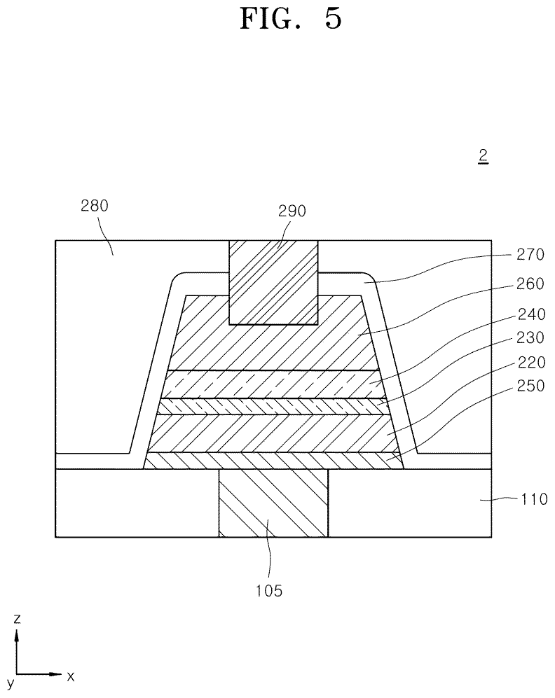

FIG. 5 is a schematic cross-sectional view illustrating a semiconductor device according to another embodiment of the present disclosure. Referring to FIG. 5, a semiconductor device 2 has a configuration with a different arrangement of a thermal confinement electrode layer 250 compared to a semiconductor device 1 described above with reference to FIG. 1.

Referring to FIG. 5, a thermal confinement electrode layer 250 is disposed on a contact plug electrode 105 and a base insulation layer 110. The thermal confinement electrode layer 250 is disposed to cover the contact plug electrode 105 and portions of the base insulation layer 110. A first electrode 220 is disposed on the thermal confinement electrode layer 250. A resistance change layer 230, an oxygen vacancy reservoir layer 240, and a second electrode 260 are sequentially disposed on the first electrode 220.

In addition, a protective insulation layer 270 is disposed over the contact plug electrode 105 and on the base insulation layer 110 to cover a side surface of the thermal confinement electrode layer 250, a side surface of the first electrode 220, a side surface of the resistance change layer 230, a side surface of the oxygen vacancy reservoir layer 240, and a side surface and an upper surface of the second electrode 260. An interlayer insulation layer 280 is disposed to cover the protective insulation layer 270. A contact electrode 290 is disposed to penetrate the interlayer insulation layer 280 and the protective insulation layer 270 and to contact the second electrode 260.

The configurations of the first electrode 220, the resistance change layer 230, the oxygen vacancy reservoir layer 240, the second electrode 260, the protective insulation layer 270, the interlayer insulation layer 280, and the contact electrode 290 are substantially the same as the configurations of the first electrode 120, the resistance change layer 130, the oxygen vacancy reservoir layer 140, the second electrode 160, the protective insulation layer 170, the interlayer insulation layer 180, and the contact electrode 190 of a semiconductor device 1 of FIG. 1. The thermal confinement electrode layer 250 is substantially the same as the thermal confinement electrode layer 150 of a semiconductor device 1 of FIG. 1, except for its arrangement within a semiconductor device 2 of FIG. 5.

The thermal confinement electrode layer 250 can serve to prevent heat from being conducted from the first electrode 220 through the thermal confinement electrode layer 250 to the contact plug electrode 105. Specifically, the thermal confinement electrode layer 250 is disposed between the contact plug electrode 105 and the first electrode 220, so that the heat generated within the resistance change layer 230 and the oxygen vacancy reservoir layer 240 during a set operation or a reset operation of the semiconductor device 2 can be suppressed from transfer to the substrate below the contact plug electrode 105 and the base insulation layer 110. Additionally, the thermal confinement electrode layer 250 can function as a connecting electrode that electrically connects the contact plug electrode 105 to the first electrode 220.

The thermal confinement electrode layer 250 may include an electrode material having lower thermal conductivity than the contact plug electrode 105 and the first electrode 220. In addition, the electrode material may be a resistor having a predetermined electrical conductivity.

In some embodiments, the semiconductor device 2 further includes a thermal confinement insulation layer corresponding to a thermal confinement insulation layer 175 of a semiconductor device 1A of FIG. 4. It is possible to further alleviate the heat inside the semiconductor device 2 from being released through side surfaces of layers in the semiconductor device 2 or through the upper surface of a second electrode 260 by using an additional thermal confinement insulation layer.

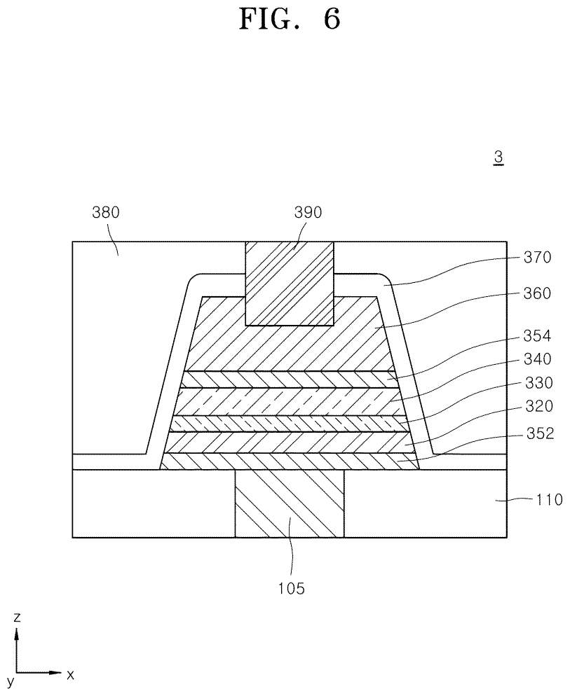

FIG. 6 is a schematic cross-sectional view illustrating a semiconductor device according to another embodiment of the present disclosure. Referring to FIG. 6, a semiconductor device 3 includes a pair of thermal confinement electrode layers arranged at different positions within the semiconductor device.

Referring to FIG. 6, a first thermal confinement electrode layer 352 is disposed on a contact plug electrode 105 and a base insulation layer 110. A first electrode 320 is disposed on the first thermal confinement electrode layer 352. A resistance change layer 330 and an oxygen vacancy reservoir layer 340 are sequentially disposed on the first electrode 320. A second thermal confinement electrode layer 354 is disposed on the oxygen vacancy reservoir layer 340. A second electrode 360 is disposed on the second thermal confinement electrode layer 354.

In addition, a protective insulation layer 370 is disposed to cover a side surface of the first thermal confinement electrode layer 352, a side surface of the first electrode 320, a side surface of the resistance change layer 330, a side surface of the oxygen vacancy reservoir layer 340, a side surface of the second thermal confinement electrode layer 354, and a side surface and an upper surface of the second electrode 360. An interlayer insulation layer 380 is disposed on the protective insulation layer 370. A contact electrode 390 is disposed to penetrate the interlayer insulation layer 380 and the protective insulation layer 370 and to contact the second electrode 360.

The configurations of the first electrode 320, the resistance change layer 330, the oxygen vacancy reservoir layer 340, the second electrode 360, the protective insulation layer 370, the interlayer insulation layer 380, and the contact electrode 390 are substantially the same as the configurations of the first electrode 120, the resistance change layer 130, the oxygen vacancy reservoir layer 140, the second electrode 160, the protective insulation layer 170, the interlayer insulation layer 180, and the contact electrode 190, respectively, which are described above with reference to FIG. 1. The configuration of the first thermal confinement electrode layer 352 is substantially the same as the configuration of a thermal confinement electrode layer 250 of a semiconductor device 2 of FIG. 5, and the configuration of the second thermal confinement electrode layer 354 is substantially the same as a configuration of a thermal confinement electrode layer 150 of a semiconductor device 1 of FIG. 1.

In an embodiment, the first thermal confinement electrode layer 352 is disposed between the contact plug electrode 105 and the first electrode 320, and the second thermal confinement electrode layer 354 is disposed between the oxygen vacancy reservoir layer 340 and the second electrode 360. Accordingly, it is possible to suppress transfer of the heat, generated inside the resistance change layer 330 and the oxygen vacancy reservoir layer 340 during set operations and reset operations of the semiconductor device 3, to the substrate through the contact plug electrode 105 and to the outside of the semiconductor device 3 through the second electrode 360 and the contact electrode 390.

In some embodiments, the semiconductor device 3 may further include a thermal confinement insulation layer corresponding to a thermal confinement insulation layer 175 of a semiconductor device 1A of FIG. 4. With this additional thermal confinement insulation layer, more suppression of heat transfer is possible to prevent the heat inside the semiconductor device 3 from being released through the side surfaces of the semiconductor device 3 or through the upper surface of the second electrode 360.

Concepts are disclosed in conjunction with various embodiments as described above. Those skilled in the art will understand that various modifications, additions, and substitutions are possible, without departing from the scope and spirit of the present disclosure. Accordingly, the embodiments disclosed in the present specification should not be considered from a restrictive standpoint but rather from an illustrative standpoint. The scope of the present disclosure is not limited to the above descriptions, and all of distinctive features within an equivalent scope should be construed as being included in the present disclosure.

What is claimed is:

1. A semiconductor device comprising:
a first electrode;
a resistance change layer disposed on the first electrode, the resistance change layer comprising oxygen vacancies;
an oxygen vacancy reservoir layer disposed on the resistance change layer;
a thermal confinement electrode layer disposed on the oxygen vacancy reservoir layer; and
a second electrode disposed on the thermal confinement electrode layer.

2. The semiconductor device of claim 1, wherein the thermal confinement electrode layer comprises an electrode material having lower thermal conductivity than the second electrode.

3. The semiconductor device of claim 2, wherein the thermal confinement electrode layer comprises metal silicon nitride.

4. The semiconductor device of claim 2, wherein the thermal confinement electrode layer comprises at least one selected from the group consisting of tungsten silicon nitride, titanium silicon nitride, and aluminum silicon nitride.

5. The semiconductor device of claim 2, wherein the thermal confinement electrode layer comprises a carbon layer with an amorphous structure.

6. The semiconductor device of claim 2, wherein the thermal confinement electrode layer comprises a nitrogen-doped carbon layer.

7. The semiconductor device of claim 1, wherein the thermal confinement electrode layer has a thickness within a range of 10 Å through 100 Å.

8. The semiconductor device of claim 1,
wherein the resistance change layer has multiple conductance values, and
wherein the multiple conductance values change in magnitude linearly depending on a voltage applied to the resistance change layer.

9. The semiconductor device of claim 1, wherein the resistance change layer comprises at least one selected from the group consisting of hafnium oxide, zirconium oxide, hafnium zirconium oxide, titanium oxide, and aluminum oxide.

10. The semiconductor device of claim 1, wherein the oxygen vacancy reservoir layer comprises at least one selected from the group consisting of tantalum (Ta), titanium (Ti), zirconium (Zr), vanadium (V), tungsten (W), and ruthenium (Ru).

11. The semiconductor device of claim 1, further comprising a thermal confinement insulation layer disposed to cover side surfaces of the resistance change layer and the oxygen vacancy reservoir layer.

12. The semiconductor device of claim 11, wherein the thermal confinement insulation layer comprises an oxide dielectric or an organic dielectric.

13. A semiconductor device comprising:
a contact plug electrode;
a first thermal confinement electrode layer disposed on the contact plug electrode;
a first electrode disposed on the first thermal confinement electrode layer;
a resistance change layer comprising oxygen vacancies and disposed on the first electrode;
an oxygen vacancy reservoir layer disposed on the resistance change layer; and
a second electrode disposed on the oxygen vacancy reservoir layer.

14. The semiconductor device of claim 13, wherein the first thermal confinement electrode layer comprises an electrode material having lower thermal conductivity than the contact plug electrode and the first electrode.

15. The semiconductor device of claim 14, wherein the first thermal confinement electrode layer comprises at least one selected from the group consisting of tungsten silicon nitride, titanium silicon nitride, and aluminum silicon nitride.

16. The semiconductor device of claim 14, wherein the first thermal confinement electrode layer comprises a carbon layer.

17. The semiconductor device of claim 13,
wherein the resistance change layer has multiple conductance values, and
wherein the multiple conductance values change in magnitude linearly depending on a voltage applied to the resistance change layer.

18. The semiconductor device of claim 13,
wherein the resistance change layer comprises at least one selected from the group consisting of hafnium oxide, zirconium oxide, hafnium zirconium oxide, titanium oxide, and aluminum oxide, and
wherein the oxygen vacancy reservoir layer comprises at least one selected from the group consisting of tantalum (Ta), titanium (Ti), zirconium (Zr), vanadium (V), tungsten (W), and ruthenium (Ru).

19. The semiconductor device of claim 13, further comprising a thermal confinement insulation layer disposed to cover side surfaces of the resistance change layer and the oxygen vacancy reservoir layer.

20. The semiconductor device of claim 19, wherein the thermal confinement insulation layer comprises an oxide dielectric or an organic dielectric material.

21. The semiconductor device of claim 13, further comprising a second thermal confinement electrode layer disposed between the oxygen vacancy reservoir layer and the second electrode.

22. The semiconductor device of claim 21, wherein the second thermal confinement electrode layer comprises an electrode material having lower thermal conductivity than the second electrode.

23. The semiconductor device of claim 13, further comprising a base insulation layer disposed to surround the contact plug electrode in a lateral direction, and
wherein the first thermal confinement electrode layer is disposed to cover the contact plug electrode and portions of the base insulation layer.
